(19) United States
(12) Patent Application Publication
(10) Pub. No.: US 2002/0048154 A1
(43) Pub. Date: Apr. 25, 2002

(54) Fin-shaped heat dissipation apparatus for electronic device

(76) Inventors: Timothy-Yu, Lin-Kou Hsiang (TW); Kelly-Shyu, Lung-Tan Hsiang (TW)

Correspondence Address: J.C. PATENTS INC., 4 Venture, Suite 250, Irvine, CA, 92618, US

(21) Appl. No.: 09/749,222

(22) Filed: Dec. 27, 2000

(30) Foreign Application Priority Data
Oct. 24, 2000 (TW) 89122366

(51) Int. Cl. H05K 7/20

(52) U.S. Cl. 361/709

(57) ABSTRACT

A fin-shaped heat dissipation apparatus for an electronic device. The fin-shaped heat dissipation apparatus has a thermal conductive plate and a fin-shaped heat sink. The fin-shaped heat sink is in a wave formed including alternative peaks and troughs. Either the troughs or the peaks are coupled to the thermal conductive plate, while the thermal conductive plate is coupled to the electronic device.

### CROSS-REFERENCE TO RELATED APPLICATION

This application claims the priority benefit of Taiwan application serial no. 89122366, filed Oct. 24, 2000.

### BACKGROUND OF THE INVENTION

1. Field of the Invention

The invention relates in general to a heat dissipation apparatus for an electronic device. More particularly, this invention relates to a fin-shaped heat dissipation apparatus for an electronic device.

2. Description of the Related Art

Since all the electronic devices consume power, for each electronic device, more or less of heat is generated from converting the power consumption into thermal energy. Under this circumstance, the longer the electronic device operates, the more heat is generated. Therefore, without a proper heat dissipation mechanism, the temperature of the electronic devices increases as it is operating. Generally speaking, any electronic device has its normal operation temperature range. Once the temperature of the electronic device is over this temperature range, the operation may be faulty. It is thus very important to provide a good heat dissipation mechanism.

FIG. 1 shows a heating dissipation apparatus used in the electronic device according to the conventional technique. The heating apparatus 10 includes a thermal conductive plate 100 and several heat sinks 110. The conductive 100 is attached on the surface of the electronic device to absorb the heat emanating from the electronic device. The used area for heat dissipation is thus increased, and the effect of heat dissipation is improved. However, this structure has the following drawbacks. As the number of the heat sinks is big, the most time-saving method for fabricating this kind of heat apparatus is to fabricate a mold. The distance between the neighboring of the heat sinks is seriously restricted. As the electronic device is made with smaller and smaller volume, the area that can be used is reduced. In addition, in this prior art, in the design of the vertical heat sinks, turbulence occurs when the air flows through the spaces between the heat sink. As a result, the circulation of the air is poor to degrade the effect of heat dissipation.

### SUMMARY OF THE INVENTION

The invention provides a fin-shaped heat dissipation apparatus applied to an electronic device that may emanate heat. The fin-shaped heat dissipation apparatus uses the wave-like structure to increase the heat dissipation area and to avoid the turbulence caused between the air flow, so as to improve the circulation of the air flow. The fin-shaped heat sink can be made of ductible material in various shapes. Therefore, even when the dimension of the electronic device shrinks, the large heat dissipation area is maintained.

In the invention, the fin-shaped heat dissipation apparatus comprises a thermal conductive plate and a fin-shaped heat sink. The thermal conductive plate is coupled to the electronic device, and the fin-shaped heat sink comprises a wave-like structure with alternate peaks and troughs with either of which coupled to the thermal conductive plate.

In another embodiment of the invention, the fin-shaped heating apparatus comprises a thermal conductive plate, a fan and at least one fin-shaped heat sink. The thermal conductive plate is coupled to the electronic device, while the fan is disposed on one surface of the thermal conductive plate. The fin-shape heat sink has a wave-like structure with alternate peaks and troughs. At least one of the peaks or troughs is coupled to the thermal conductive plate.

Both the foregoing general description and the following detailed description are exemplary and explanatory only and are not restrictive of the invention, as claimed.

### BRIEF DESCRIPTION OF THE DRAWINGS

FIG. 1 shows a conventional heat dissipation apparatus;

FIG. 2A shows an external structure of a heat dissipation apparatus according to the invention.

FIG. 2B shows a front view of the heat dissipation apparatus as shown in FIG. 2A;

FIG. 2C shows a side view of the heat dissipation apparatus as shown in FIG. 2A;

FIG. 3A shows an external structure of a heat dissipation apparatus in a second embodiment of the invention;

FIG. 3B shows a front view of the heat dissipation apparatus as shown in FIG. 3A;

FIG. 3C shows a side view of the heat dissipation apparatus as shown in FIG. 3A;

FIG. 4A shows an external structure of a heat dissipation apparatus in a third embodiment of the invention;

FIG. 4B shows a rear view of the heat dissipation apparatus as shown in FIG. 4A;

FIG. 4C shows a side view of the heat dissipation apparatus as shown in FIG. 4A;

FIG. 5A shows an external structure of a heat dissipation apparatus in a fourth embodiment of the invention;

FIG. 5B shows a front view of the heat dissipation apparatus as shown in FIG. 5A;

FIG. 5C shows a side view of the heat dissipation apparatus as shown in FIG. 5A;

FIG. 6A shows an external structure of a heat dissipation apparatus in a fifth embodiment of the invention;

FIG. 6B shows a front view of the heat dissipation apparatus as shown in FIG. 6A;

FIG. 6C shows a side view of the heat dissipation apparatus as shown in FIG. 6A;

FIG. 7 shows an external structure of a heat dissipation apparatus in a sixth embodiment of the invention;

FIG. 8 shows an external structure of a heat dissipation apparatus in a seventh embodiment of the invention; and

FIG. 9 shows an external structure of a heat dissipation apparatus in a eighth embodiment of the invention.

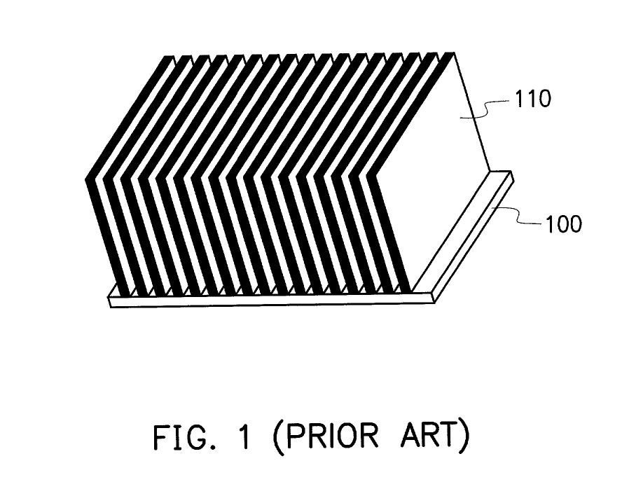

### DESCRIPTION OF THE PREFERRED EMBODIMENTS

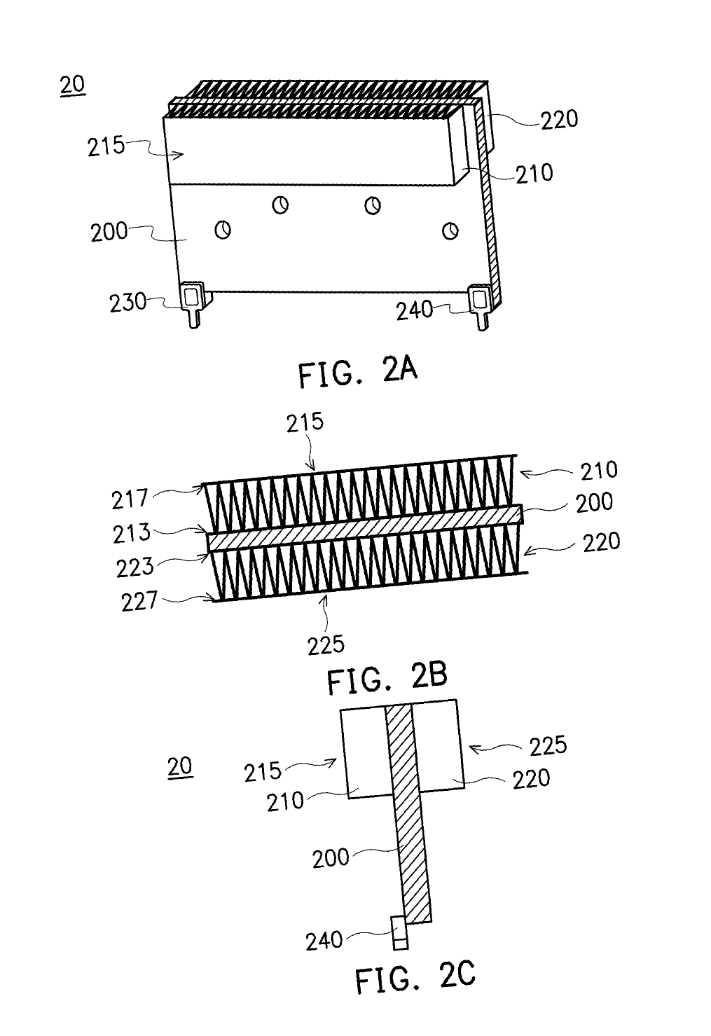

FIG. 2A shows an external layout of a first embodiment according to the invention. In the first embodiment, a fin-shaped heat dissipation apparatus 20 for an electronic device is provided. The fin-shaped heat dissipation apparatus 20 comprises a thermal conductive plate 200 and two fin-shaped heat sinks 210 and 220. Referring to FIG. 2B and FIG. 2C, the fin-shaped heat sinks 210 is in a zigzag structure, or a wave structure that comprises alternate peaks 213 and troughs 217. Similarly, the fin-shaped heat sink 220 is in a zigzag structure, or a wave structure that comprises alternate peaks 227 and troughs 223. The troughs 213 and 223 of the fin-shaped heat sinks 210 and 220 are coupled to two surfaces of the thermal conductive plate 200. Thereby, when the thermal conductive plate 200 is in contact with a surface of an electronic device, the heat emanating from the surface of the electronic device can be conducted through the thermal conductive plate 200 to the fin-shaped heat sinks 210 and 220.

In addition, the peaks 217 of the heat sink 210 are coupled to an outer thermal conductive plate 215, while the peaks 227 of the heat sink 210 are coupled to the other outer thermal conductive plate 225. Two positioning devices 230 and 240 are disposed on two sides of the thermal conductive plate 200 to position and fix the heat dissipation apparatus 20 on a position where the heat emanating from the electronic device.

It is appreciate that the outer thermal conductive plates 215 and 225 and the positioning devices 230 and 240 are not the necessary devices in the heating apparatus 20. The peaks and the troughs are only the relative positions. That is, viewing from another angle or direction, the peaks 217 and 227 can be treated as troughs 213 and 223, while the troughs 213 and 223 can be treated as peaks 217 and 227.

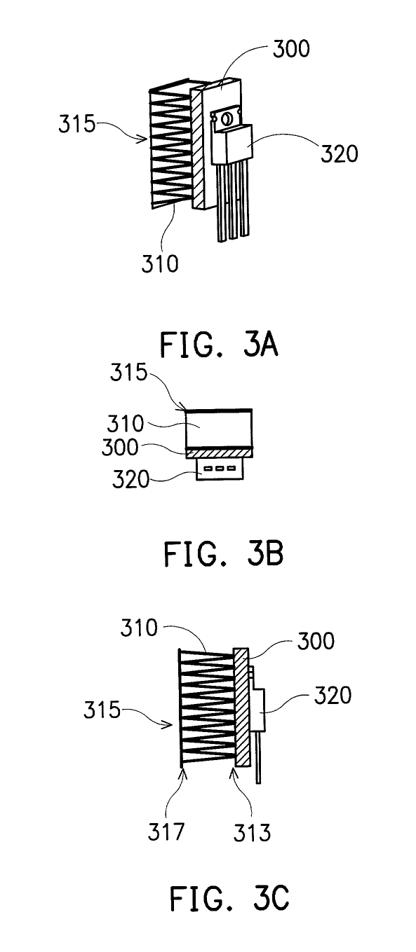

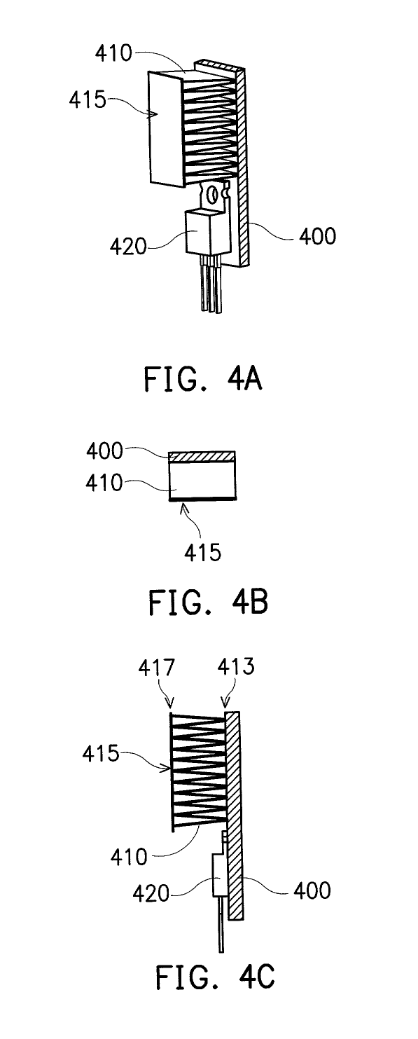

Referring to FIG. 3A, 3B and 3C, an external layout, a front view and a side view of a second embodiment according to the invention are illustrated. The heat dissipation apparatus 30 comprises a thermal conductive plate 300, a fin-shaped heat sink 310 and an outer thermal conductive plate 315. The thermal conductive plate 300 has a first surface attached on an electronic device 320, and a second surface opposite to the first surface with the fin-shaped heat sink 310 attached thereon. It is appreciated that the fin-shaped heat sink 310 may also be attached on other parts of the thermal conductive plate 300. For example, FIGS. 4A, 4B and 4C show another layout of the similar structure as shown in FIGS. 3A, 3B and 3C. In the third embodiment as shown in FIGS. 4A, 4B and 4C, the electronic device 420 and the fin-shaped heat sink 410 are coupled to the same surface of the thermal conductive plate 400.

Again, the outer thermal conductive plates 315 and 415 in the third and fourth embodiments are not the necessary devices, though they provide an extra surface for heat dissipation. The peaks 317, 417 and the troughs 313 and 413 are also relative positions which will vary while viewing from different angle or direction.

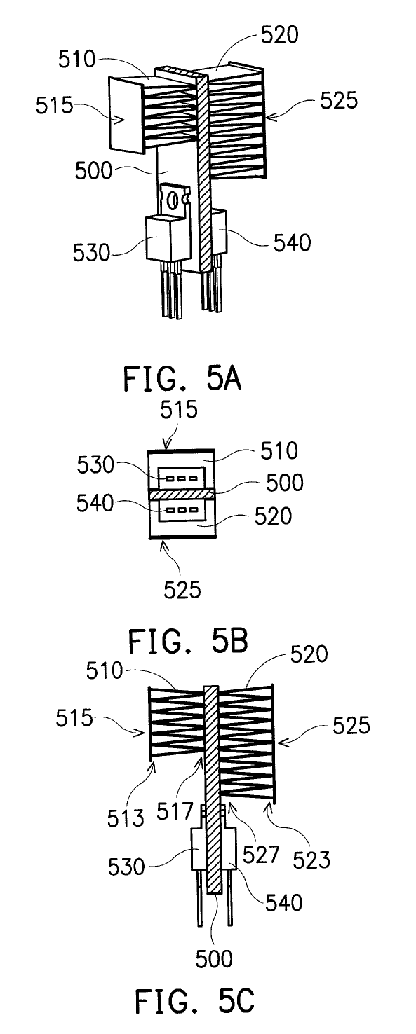

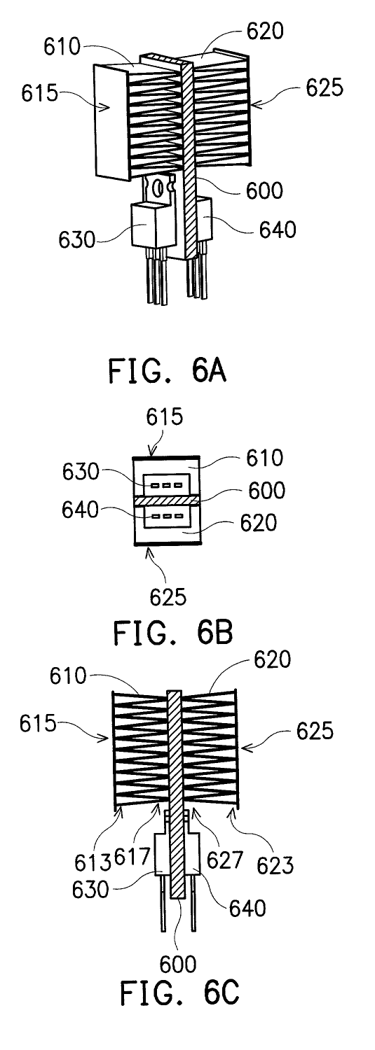

FIGS. 5A, 5B and 5C illustrate a fourth embodiment of the invention. In this embodiment, the heat dissipation apparatus 50 comprises a thermal conductive plate 500, two fin-shaped heat sinks 510 and 520, and two outer thermal conductive plates 515 and 525. The fin-shaped heat sinks 510 and 520 have first sides attached on two surfaces of the thermal conductive plate 500, and the outer thermal conductive plates 515 and 525 are attached on the second sides opposite to the first sides of the fin-shaped heat sinks 510 and 520. Two electronic devices 530 and 540 are also coupled to these two surfaces of the thermal conductive plate 500. That is, on each surface of the thermal plate 500, one electronic device 530 or 540 and one fin-shaped heat sink 510 or 520 are coupled. In this embodiment, the fin-shaped heat sinks 510 and 520 are in different lengths. It is appreciate that the invention is not restricted to this particular feature. The fin-shaped heat sinks 510 and 520 can also be formed with identical dimensions or in the same length, however, with different width or thickness. FIGS. 6A, 6B and 6C illustrate a fifth embodiment of the invention in which the fin-shaped heat sinks 610 and 620 have an identical length.

Comparing the fourth and the fifth embodiments, the outer thermal conductive plates 515, 525, 615 and 625 are not the necessary devices. The heat dissipation apparatus 50 and 60 can function as required without these structures, though they provide a better heat dissipation effect. In addition, the peaks 517, 527, 617 and 627 and the troughs 513, 523, 613 and 623 are relative positions that can be varied by view from different angle or direction.

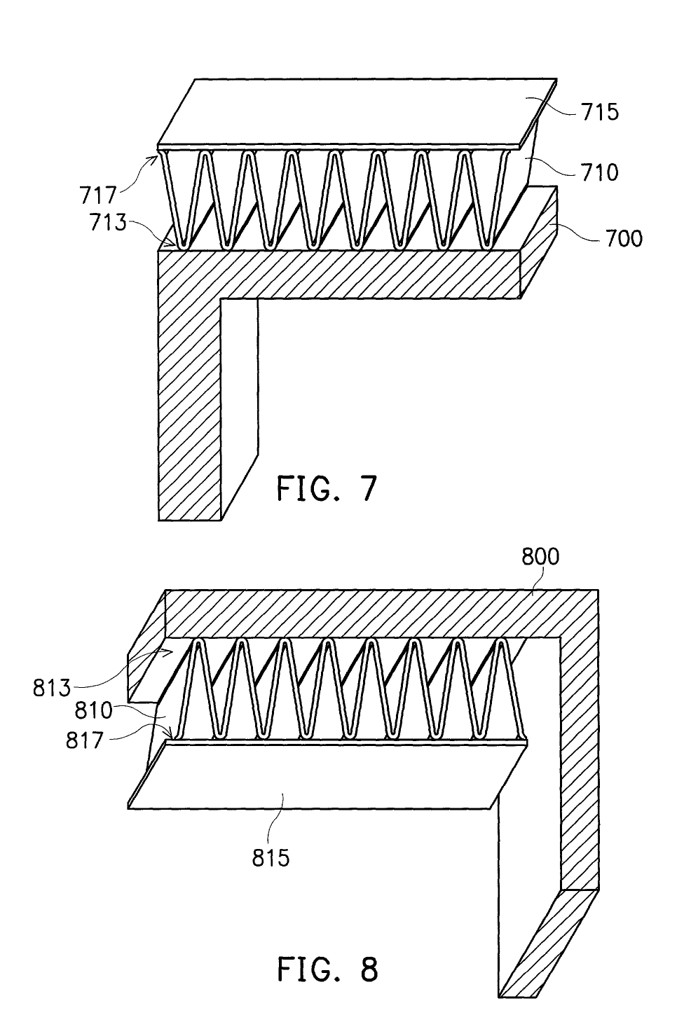

In FIG. 7, a sixth embodiment of the invention is illustrated. The structure of the fin-shaped heat sink is clearly shown. The heat dissipation apparatus 70 comprises a thermal conductive plate 700, a fin-shaped heat sink 710 and an outer thermal conductive plate 715. The fin-shaped heat sink 710 is in a wave-like structure that includes alternate peaks 717 and troughs 713. The troughs 713 are coupled on a surface of the thermal conductive plate 700, and the peaks 717 are coupled to the outer thermal conductive plate 715. Again, the outer thermal conductive plate 715 is an additional structure that does not affect the function of the heat dissipation apparatus 70, and the peaks 717 and troughs 713 can be interchanged by viewing from another angle or direction.

FIG. 8 shows a seventh embodiment of the invention. The heat dissipation apparatus 80 comprises a thermal conductive plate 800, a fin-shaped heat sink 810 and an outer thermal conductive plate 815. The fin-shaped heat sink 810 comprises a wave-like structure having alternate peaks 817 and troughs 813. The troughs 813 are coupled to the surface of the thermal conductive plate 800 and the peaks 817 are coupled to the outer thermal conductive plate 815. The outer thermal conductive plate 715 is an additional structure that does not affect the function of the heat dissipation apparatus 70, and the peaks 717 and troughs 713 can be interchanged by viewing from another angle or direction.

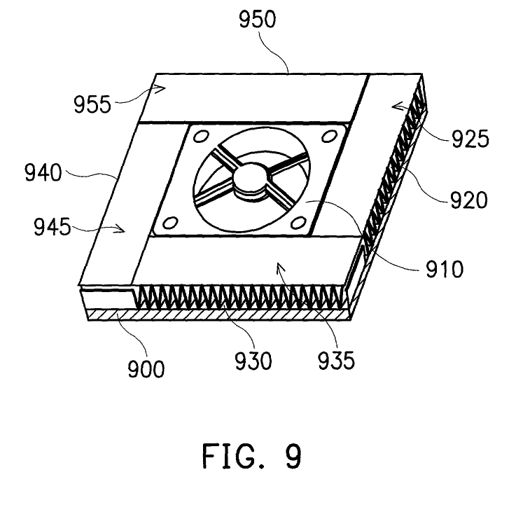

In FIG. 9, an eighth embodiment based on the seventh embodiment as shown in FIG. 8 is illustrated. The heat dissipation apparatus 90 comprises a thermal conductive plate 900, a fan 910, several fin-shaped heat sinks 920, 930, 940 and 950. The thermal conductive plate 900 is coupled on a surface of an electronic device. The fan 910 is disposed on one surface of the thermal conductive plate 900. Around the fan 910, the fin-shaped heat sinks 920, 930, 940 and 950 are installed on the surface of the thermal conductive plate 900 on which the fan 910 is disposed. On the surfaces of the fin-shaped heat sinks 920, 930, 940 and 950 opposite to the surfaces attached on the thermal conductive plate 900, outer thermal conductive plates 925, 935, 945 and 955 are disposed. The outer thermal conductive plates 925, 935, 945 and 955 provide a better thermal conductive path but are not necessary. The fin-shaped heat sinks 920, 930, 940 and 950 can be arranged on other places instead of being around the fan 910. On both sides of the fan 910, the fin-shaped heat sink can also be disposed.

According to the above, the invention provides a wave-like heat sink to increase the heat dissipation area and improve the circulation of the air flow. When the fin-shaped heat sink is made of a material with high ductiblility, different shapes can also be formed. Therefore, even when the dimension of the electronic devices shrinks, the large heat dissipation area is maintained.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A fin-shaped heat dissipation apparatus for an electronic device, comprising:
a thermal conductive plate, coupled on a surface of the electronic device; and
a first fin-shaped heat sink with a wave-like structure, the wave-like structure having alternate peaks and troughs, and either the peaks or the troughs being coupled to the thermal conductive plate.

2. The fin-shaped heat dissipation apparatus according to claim 1, wherein the first fin-shaped heat sink is further coupled to a first outer thermal conductive plate.

3. The fin-shaped heat dissipation apparatus according to claim 1, wherein the troughs are coupled to the thermal conductive plate, the peaks are coupled to a first outer thermal conductive plate.

4. The fin-shaped heat dissipation apparatus according to claim 1, further comprises a second fin-shaped heat sink coupled on the thermal conductive plate opposite to the first fin-shaped heat sink, the second fin-shaped heat sink comprising alternative peaks and troughs.

5. The fin-shaped heat dissipation apparatus according to claim 4, wherein when the peaks of the second fin-shaped heat sink are coupled to the conductive plate, the troughs of the second fin-shaped heat sink are coupled to a second outer thermal conductive plate.

6. The fin-shaped heat dissipation apparatus according to claim 4, wherein the troughs are coupled to the thermal conductive plate, the peaks are coupled to an outer thermal conductive plate.

7. The fin-shaped heat dissipation apparatus according to claim 4, wherein the first and the second fin-shaped heat sinks are in different sizes.

8. The fin-shaped heat dissipation apparatus according to claim 1, further comprising a second fin-shaped heat sink coupled to the thermal conductive plate on the same surface where the first fin-shaped heat sink is coupled.

9. The fin-shaped heat dissipation apparatus according to claim 8, wherein the second fin-shaped heat sink is further coupled to a second outer thermal conductive plate.

10. A fin-shaped heat dissipation apparatus coupled to an electronic device, comprising:
a thermal conductive plate, coupled to the electronic device;
a fan, disposed on a surface of the thermal conductive plate; and
at least a fin-shaped heat sink around the fan, the fin-shaped heat sink having a wave-like structure with alternate troughs and peaks, and either the troughs or the peaks are coupled to the thermal conductive plate.

11. The fin-shaped heat dissipation apparatus according to claim 10, wherein the fin-shaped heat sink is further coupled to an outer thermal conductive plate.

12. The fin-shaped heat dissipation apparatus according to claim 10, wherein at least one of the troughs is coupled to the thermal conductive plate, while at least one of the peaks is coupled to an outer thermal conductive plate.
